(19) United States
(12) Patent Application Publication
(10) Pub. No.: US 2012/0182490 A1
(43) Pub. Date: Jul. 19, 2012

(54) ARRAY SUBSTRATE AND METHOD FOR MANUFACTURING THE SAME

(75) Inventors: Won Seok KIM, Beijing (CN); Pil Seok KIM, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 13/239,727

(22) Filed: Sep. 22, 2011

(30) Foreign Application Priority Data
Jan. 18, 2011 (CN) 201110020246.1

(51) Int. Cl. G02F 1/136; H01L 33/08

(52) U.S. Cl. 349/43; 438/30; 257/E33.053

(57) ABSTRACT

An array substrate comprises gate lines and data lines for defining pixel regions. A thin film transistor, a common electrode, and a pixel electrode with strip electrodes are formed in each pixel region, the common electrode is formed on a second insulating layer which covers the data line, the pixel electrode is formed on a third insulating layer which covers the common electrode. Thus, the area of the display region can be increased, and aperture ratio can be effectively improved.

### BACKGROUND

Embodiments of the disclosed technology refer to an array substrate of a thin film transistor liquid crystal display and a method for manufacturing the same.

In the thin film transistor liquid crystal display (TFT-LCD) technology, Advanced-Super Dimensional Switching (AD-SDS) is one of the technologies for improving the display quality of a LCD.

An AS-SDS LCD forms a multi-dimensional space composite field by a parallel electric field generated by edges of pixel electrodes in the same plane and a vertical electric field generated between common electrodes and pixel electrodes, so that liquid crystal molecules between the pixel electrodes within a liquid crystal unit and immediately above the electrodes can rotate in all orientations, thereby improving work efficiency of in-plane orientation type liquid crystal and increasing the light transmission efficiency. AS-SDS can improve the display quality of a TFT-LCD, and has advantages of high transmittance, wide viewing angle, high aperture ratio, low chromatic aberration, short response time, free of push Mura, etc.

Typically, the main structure of a TFT-LCD comprises an array substrate and a color filter substrate forming a cell with a liquid crystal layer interposed therebetween. Gate lines, data lines, pixel electrodes, common electrodes and thin film transistors are formed on the array substrate. A color resin pattern and a black matrix pattern are formed on the color filter substrate.

With an increasing demand for TFT-LCDs in market, the requirement of high aperture ratio is continuously raised. It has been proposed a technology of using a resin passivation layer to improve aperture ratio. However, since the material of the resin passivation is expensive, and the requirements for the coating apparatus and the processes are strict (a coating thickness is less that 1.5 μm), and the cost of this technology is relatively high. It has been proposed another technology of changing the positions of the common electrode and the pixel electrode to improve aperture ratio. Compared with disposing the common electrode on the base substrate and disposing the pixel electrodes on a passivation layer on the array substrate of a conventional AD-SDS TFT-LCD, this technology disposes the pixel electrodes in a same layer as the data lines and disposes the common electrode on a passivation layer. Studies have shown that a light leakage phenomenon appears between a pixel electrode and a data line in this technology, which restricts the increase of aperture ratio. The reason is that the liquid crystal marital in some area is driven by a multi-dimensional space composite field, while the liquid crystal material in other area is driven by a transverse field (i.e., In-Plane Switching mode).

### SUMMARY

The embodiment of the disclosed technology provides an array substrate of a thin film transistor liquid crystal display, comprising: a base substrate; gate lines and data lines for defining pixel regions on the base substrate, wherein in each of the pixel regions, a common electrode and a pixel electrode having strip electrodes, which form a multi-dimensional space composite field in cooperation, and a thin film transistor are formed, and wherein the common electrodes are formed on a second insulating layer which covers the gate lines, the data lines, and the thin film transistors, the pixel electrodes are formed on a third insulating layer which covers the common electrodes.

The embodiment of the disclosed technology further provides a method for manufacturing an array substrate of a thin film transistor liquid crystal display, comprising:

Step 1, forming gate lines and gate electrodes on a base substrate;

Step 2, forming data lines, and an active layer, source electrodes and drain electrodes of thin film transistors on the base substrate after step 1;

Step 3, forming a second insulating layer comprising first and second via holes on the base substrate after step 2, the first via holes are positioned in a gate line bonding area, and the second via holes are positioned in a data line bonding area;

Step 4, forming common electrodes, gate connecting electrodes, and data connecting electrodes on the base substrate after step 3, wherein third via holes are formed in the common electrodes at positions of the drain electrodes, the gate connecting electrodes are connected with the gate lines via the first via holes, and the data connecting electrodes are connected with the data lines via the second via holes;

Step 5, forming a third insulating layer on the base substrate after step 4, and forming fourth via holes in the third insulating layer at the positions of the drain electrodes so as to expose a surface of the drain electrodes, wherein the fourth via holes are located within the third via holes; and

Step 6, forming pixel electrodes on the base substrate after step 5, the pixel electrodes are connected with the drain electrodes through the fourth via holes.

Further scope of applicability of the disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 is a plan view of an array substrate of a TFT-LCD of the disclosed technology;

FIG. 2 is a cross-sectional view taken along a line A1-A1 in FIG. 1;

FIG. 3 is a cross-sectional view taken along a line B1-B1 in FIG. 1;

FIG. 4 is a plan view of the array substrate of the TFT-LCD of the disclosed technology after a first patterning process;

FIG. 5 is a cross-sectional view taken along a line A2-A2 in FIG. 4;

FIG. 6 is a plan view of the array substrate of the TFT-LCD of the disclosed technology after a second patterning process;

FIG. 7 is a cross-sectional view taken along a line A3-A3 in FIG. 6;

FIG. 8 is a cross-sectional view taken along a line B3-B3 in FIG. 6;

FIG. 9 is a plan view of the array substrate of the TFT-LCD of the disclosed technology after a third patterning process;

FIG. 10 is a cross-sectional view taken along a line A4-A4 in FIG. 9;

FIG. 11 is a cross-sectional view taken along a line B4-B4 in FIG. 9;

FIG. 12 is a cross-sectional view of a gate line bonding area in FIG. 9;

FIG. 13 is a cross-sectional view of a data line bonding area in FIG. 9;

FIG. 14 is a plan view of the array substrate of the TFT-LCD of the disclosed technology after a fourth patterning process;

FIG. 15 is a cross-sectional view taken along a line A5-A5 in FIG. 14;

FIG. 16 is a cross-sectional view taken along a line B5-B5 in FIG. 14;

FIG. 17 is a cross-sectional view of a gate line bonding area in FIG. 14;

FIG. 18 is a cross-sectional view of a data line bonding area in FIG. 14;

FIG. 19 is a plan view of the array substrate of the TFT-LCD of the disclosed technology after a fifth patterning process;

FIG. 20 is a cross-sectional view taken along a line A6-A6 in FIG. 19; and

FIG. 21 is a cross-sectional view taken along a line B6-B6 in FIG. 19.

### DETAILED DESCRIPTION

The technology of the disclosed technology is further described in detail with reference to the following drawings and embodiments. The thickness of respective thin film layer and the size of regions in the drawings are not drawn in real scale of an array substrate of a TFT-LCD, and it is only for a purpose of illustrating the disclosed technology.

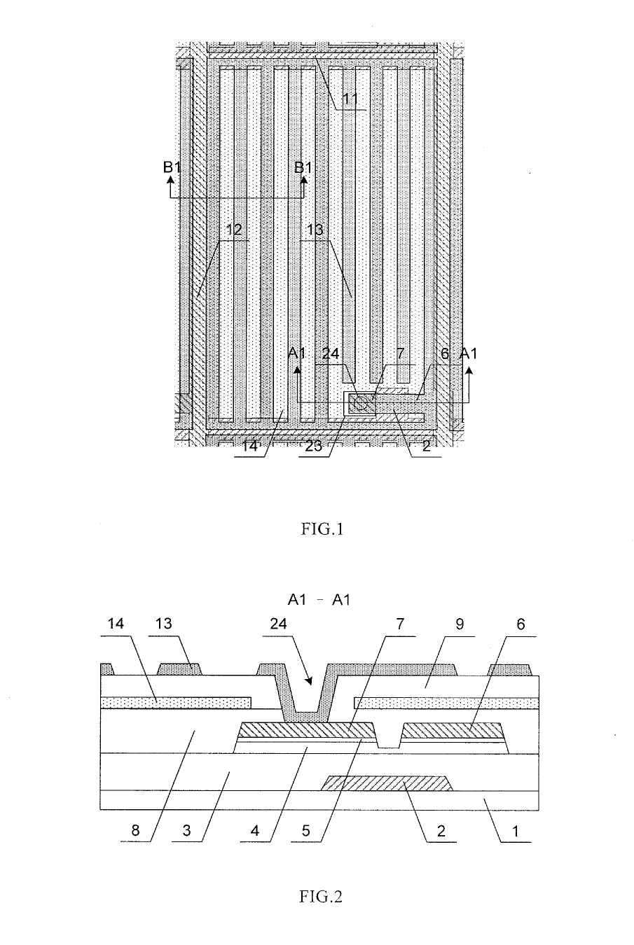

FIG. 1 is a plan view of an array substrate of a TFT-LCD according to a first embodiment of the disclosed technology, showing a structure of one pixel region, FIG. 2 is a cross-sectional view taken along a line A1-A1 in FIG. 1, and FIG. 3 is a cross-sectional view taken along a line B1-B1 in FIG. 1.

As shown in FIGS. 1-3, a main structure of the array substrate of the TFT-LCD according to the embodiment of the disclosed technology comprises gate lines 11, date lines 12, pixel electrodes 13, common electrodes 14, and thin film transistors (TFTs) formed on a base substrate 1. The gate lines 11 and the date lines 12 define a pixel region; and one pixel electrode 13, the common electrode 14, and the thin film transistor are formed in each pixel region. Each gate line 11 is adapted to provide a turn-on (ON) signal or a turn-off (OFF) signal to the thin film transistor in each pixel region. Each data line 12 is adapted to provide a date signal to the pixel electrode 13. Each pixel electrode 13 comprises a plurality of strip electrodes arranged in sequence, and is adapted to form a multi-dimensional space composite field together with the common electrode 14. The common electrode 14 is formed on a second insulating layer 8 which covers the data lines 12, and the pixel electrode 13 is formed on a third insulating layer 9 which covers the common electrodes 14. Edge portions of the pixel electrode 13 are overlapped with and located over the data lines 12 (as shown in FIGS. 2 and 3), so the region between the pixel electrodes 13 and the data lines 12 become a part of display area, and aperture ratio can be effectively improved.

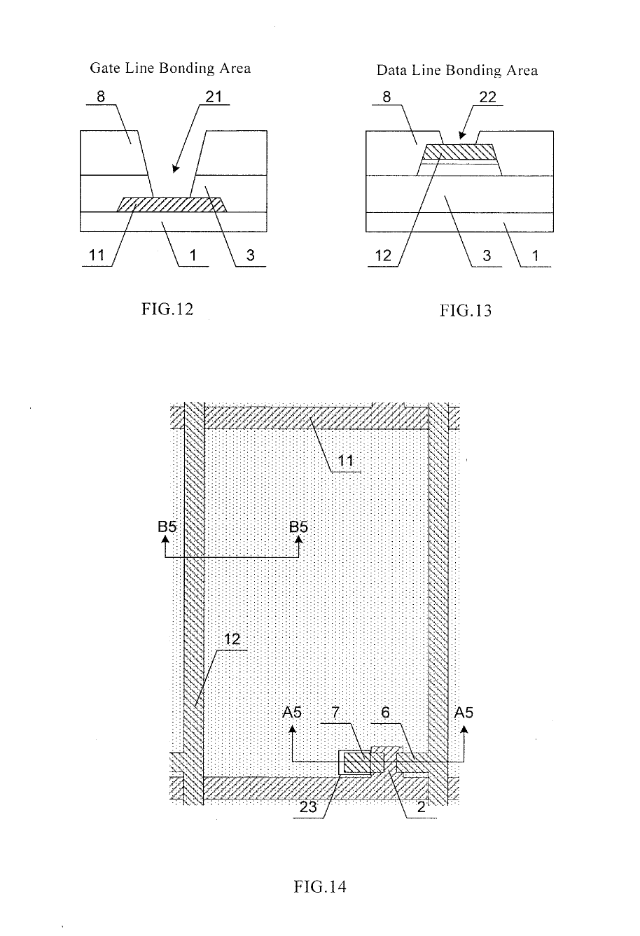

Specifically, the array substrate of the TFT-LCD according to the embodiment of the disclosed technology comprises: gate lines 11 and gate electrodes 2 formed on the base substrate 1, each gate electrode 2 is connected with one gate line 11. A first insulating layer 3 is formed on the gate lines 11 and the gate electrodes 2 and covers the entire base substrate 1. An active layer (comprising a semiconductor layer 4 and a doped semiconductor layer 5) of the thin film transistor in each pixel region is formed on the first insulating layer 3 and is located above each gate electrode 2; a source electrode 6 and a drain electrode 7 are located on the active layer, one end of the source electrode 6 is located above the gate electrode 2, the other end is connected with one date line 12, while one end of the drain electrode 7 is located above the gate electrode 2, and the other end is connected with the pixel electrode 13. A TFT channel region is defined between the source electrode 6 and the drain electrode 7. The doped semiconductor layer 5 in the TFT channel region is completely removed, and a part of the thickness of the semiconductor layer 4 is also removed, so that the semiconductor layer 4 in the TFT channel region is exposed. A second insulating layer 8 is formed on the resultant structure, first via holes 21 are opened in a gate line bonding area of the second insulating layer, and second via holes 22 are opened in a data line bonding area, as shown in FIGS. 12 and 13. The gate line bonding area and the data line bonding area are generally positioned at the peripheral area of the array substrate, and are adapted to connect the gate lines and the data lines with a driver chip, respectively. The common electrodes 14, gate connecting electrodes, and data connecting electrodes are formed on the second insulating layer 8. A third via hole 23 is opened in the common electrode 14 in the region where each drain electrode 7 is located, each gate connecting electrode formed in the gate line bonding area is connected with one gate line 11 through one first via hole, and each data connecting electrode formed in the data line bonding area is connected with one data line 12 through one second via hole. A third insulating layer 9 is formed on the resultant structure, a fourth via hole 24 is opened at the position corresponding to each drain electrode 7 to expose the surface of the drain electrode 7, the area of the fourth via hole 24 is smaller than that of the third via hole 23, that is, the region of the third via hole 23 covers the region of the fourth via hole 24. Each pixel electrode 13, comprising a plurality of strip electrodes arranged in parallel and in sequence, is formed on the third insulating layer 9. The plurality of strip electrodes are connected with each other, and also are connected with one drain electrode 7 through one fourth via hole 24 in each pixel region.

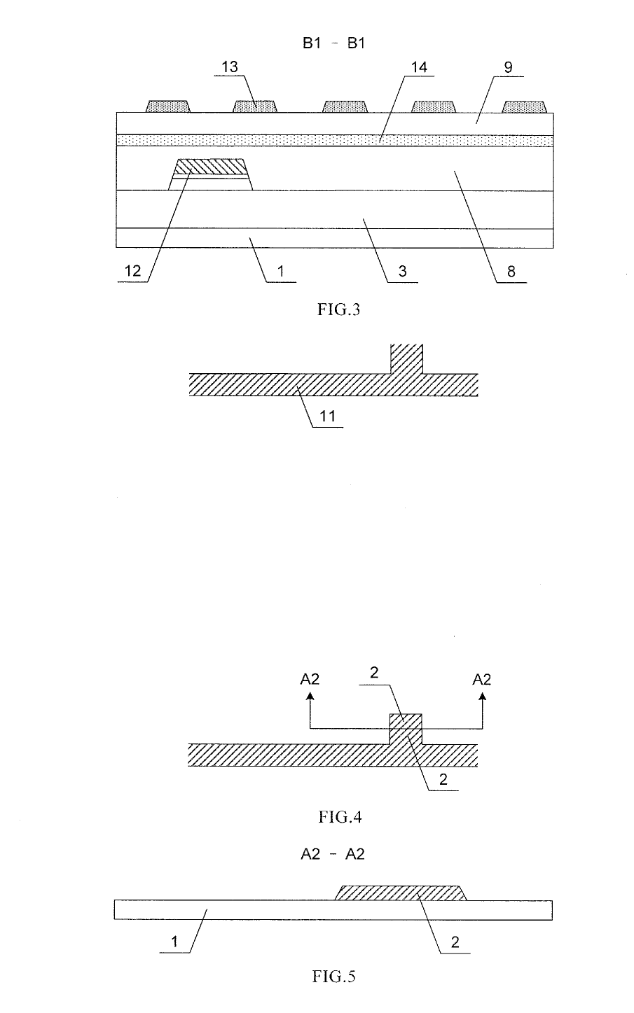

FIGS. 4-21 are schematic views of the manufacture procedure of the array substrate of the TFT-LCD according to the embodiment of the disclosed technology, further illustrating the embodiment of the disclosed technology. Hereinafter, a patterning process referred to in the following description may comprise coating photoresist, masking, exposing and developing of photoresist, etching by using a photoresist pattern, and removing photoresist, etc., in which photoresist is of positive photoresist type, for example.

FIG. 4 is a plan view of the array substrate of the TFT-LCD of the disclosed technology after a first patterning process, showing a structure of one pixel region, and FIG. 5 is a cross-sectional view taken along a line A2-A2 in FIG. 4.

Firstly, a gate metal thin film is deposited on the base substrate 1 (e.g., a glass substrate or a quartz substrate) by a magnetron sputtering method or a thermal evaporating method, and then the gate metal thin film is patterned by a patterning process with a common mask plate, so as to form a pattern comprising gate lines 11 and gate electrodes 2 each connected to one gate line 11, as shown in FIGS. 4 and 5.

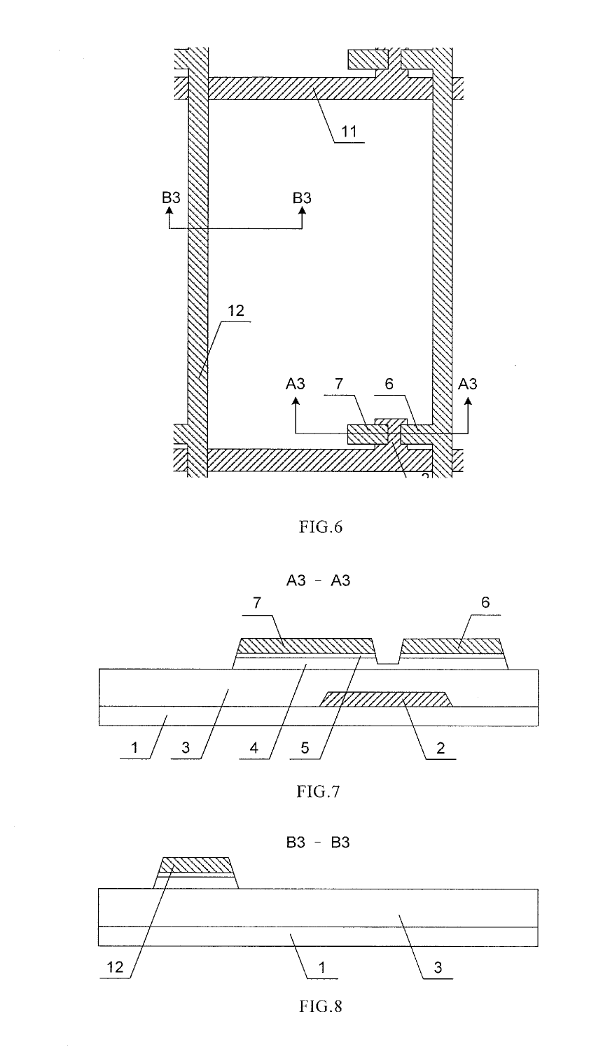

FIG. 6 is a plan view of the array substrate of the TFT-LCD of the disclosed technology after a second patterning process, showing a structure of one pixel region, and FIG. 7 is a cross-sectional view taken along a line A3-A3 in FIG. 6, and FIG. 8 is a cross-sectional view taken along a line B3-B3 in FIG. 6.

On the substrate after the pattern as shown in FIG. 4 has been formed, one first insulating layer is coated at first by a spin coating method, and then a semiconductor thin film and a doped semiconductor thin film are deposited in sequence by a plasma enhanced chemical vapor deposition (PECVD) method. These layers are patterned by a patterning process with a half-tone mask plate or a gray-tone mask plate, to form a pattern comprising data lines 12 and an active layer, source electrodes 6, and drain electrodes 7 of thin film transistors, as shown in FIGS. 6-8. In each TFT, the active layer (comprising a semiconductor layer 4 and a doped semiconductor layer 5 which are stacked together) is formed on the first insulating layer 3 and is located over the gate electrode 2; the source electrode 6 and the drain electrode 7 are formed on the active layer; one end of the source electrode 6 is located above the gate electrode 2, and the other end is connected with the data line 12, while one end of the drain electrode 7 is located above the gate electrode 2, opposite to the source electrode 6. A channel region is defined between the source electrode 6 and the drain electrode 7, the doped semiconductor layer 5 in the channel region is completely removed, and a part of the thickness of the semiconductor layer 4 is also removed, so that the semiconductor layer 4 in the channel region is exposed.

This patterning process is a patterning process of a multi-step etching method, and is same as the procedure for forming patterns comprising the data lines, the active layer, the source electrodes, the drain electrodes and the channel regions by a common four-mask processes, which is described in detail as follows.

A photoresist layer is coated on a source and drain metal thin film, and is exposed by using a half-tone mask plate or a gray tone mask plate, and the developed photoresist forms a completely exposed region (by completely removed photoresist region), an unexposed region (by completely remained photoresist region), and a partially exposed region (by partially remained photoresist region), wherein the unexposed region corresponds to a region where a data line pattern, a source electrode pattern, and a drain electrode pattern are formed, the partially exposed region corresponds to a region where a TFT channel region pattern is formed, and the completely exposed region corresponds to a region except for the above patterns. The source and drain metal thin film, the doped semiconductor thin film, and the semiconductor film in the completely exposed region are removed in a first etch process, so as to form the pattern comprising the active layer and the data lines. The photoresist in the partially exposed region is removed in an ashing process, so as to expose the source and drain metal thin film in this region while reduce the thickness of the photoresist in the unexposed region. The source and drain metal thin film and the doped semiconductor thin film in the partially exposed region are completely removed and a part of the thickness of the semiconductor thin film is etched in a second etching process, so as to expose the semiconductor thin film in this region and form the pattern comprising the source electrodes, the drain electrodes, and the channel regions of the thin film transistors. Since the active layer and the data lines are formed in a same patterning process, the semiconductor thin film and the doped semiconductor thin film below the data lines are remained.

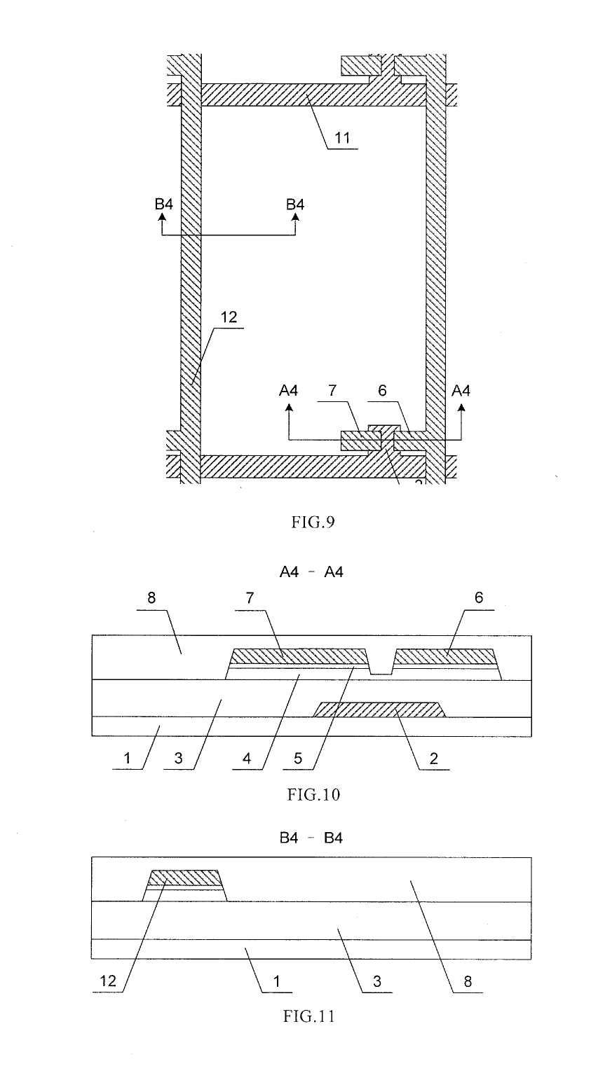

FIG. 9 is a plan view of the array substrate of the TFT-LCD of the disclosed technology after a third patterning process, showing a structure of one pixel region, FIG. 10 is a cross-sectional view taken along a line A4-A4 in FIG. 9, FIG. 11 is a cross-sectional view taken along a line B4-B4 in FIG. 9, FIG. 12 is a cross-sectional view of a gate line bonding area in FIG. 9, and FIG. 13 is a cross-sectional view of a data line bonding area in FIG. 9.

A second insulating layer is coated on the substrate with the pattern as shown in FIG. 6, by a spin coating method, and then is patterned in a patterning process with a common mask plate, so as to form a pattern comprising first via holes 21 and second via holes 21. The first via holes 21 are positioned in the gate line bonding area, the first insulating layer 3 and the second insulating layer 8 within the first via holes 21 are removed by etching, to expose the surface of the gate lines 11; the second via holes 22 are positioned in the data line bonding area, the second insulating layer 8 within the second via holes 22 is removed by etching, to expose the surface of the data lines 12, as shown in FIGS. 9-13.

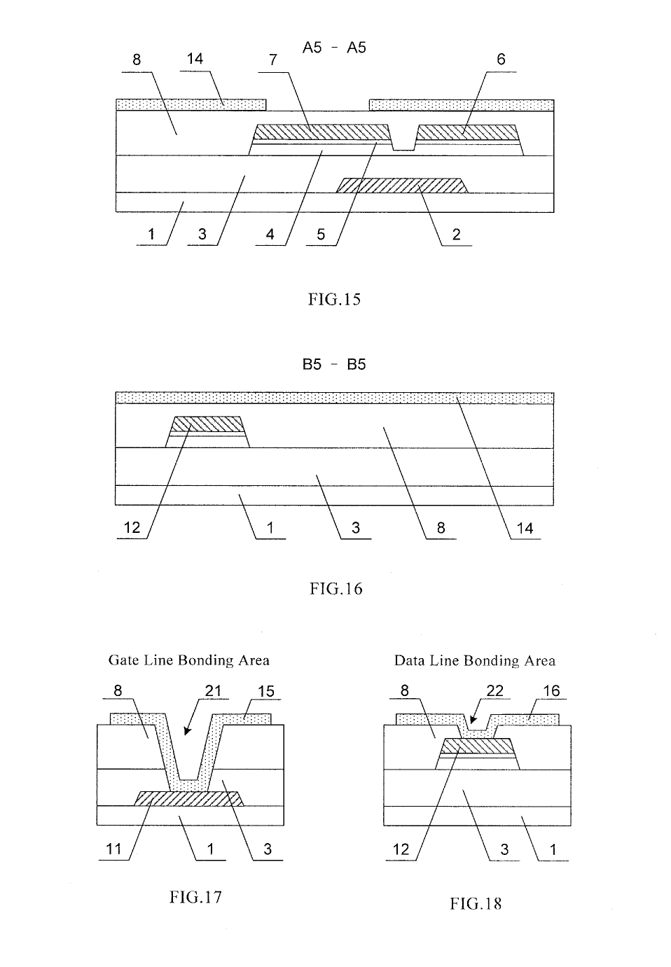

FIG. 14 is a plan view of the array substrate of the TFT-LCD of the disclosed technology after a fourth patterning process, showing a structure of one pixel region, FIG. 15 is a cross-sectional view taken along a line A5-A5 in FIG. 14, FIG. 16 is a cross-sectional view taken along a line B5-B5 in FIG. 14, FIG. 17 is a cross-sectional view of the gate line bonding area in FIG. 14, and FIG. 18 is a cross-sectional view of the data line bonding area in FIG. 14.

A first conductive thin film is deposited on the substrate with the pattern as shown in FIG. 9 by a magnetron sputtering method or a thermal evaporating method, and then is patterned by a patterning process with a common mask plate, so as to form a pattern comprising the common electrodes 14, the gate connecting electrodes 15, and the date connecting electrodes 16. The common electrodes 14 cover the pixel region, but the third via holes 23 are formed in a region where each drain electrode 7 is formed, and the second insulating layer 8 is exposed by the third via hole 23. Each gate connecting electrode 15 is formed in the gate line bonding area and covers a first via hole 21 so as to be connected with one gate line 11; each data connecting electrode 16 is folioed in the data line bonding area and covers a second via hole 22 so as to be connected with one data line 12, as shown in FIGS. 14-18.

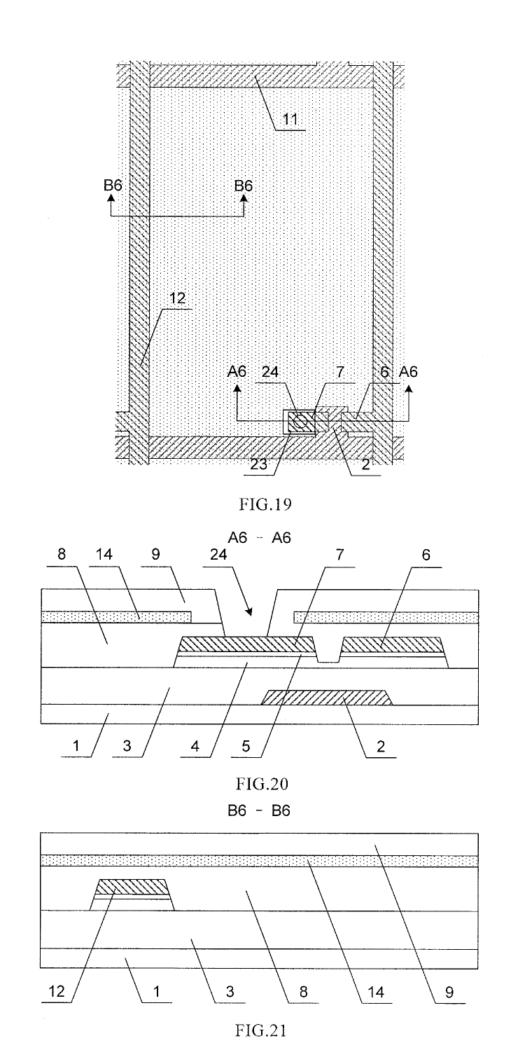

FIG. 19 is a plan view of the array substrate of the TFT-LCD of the disclosed technology after a fifth patterning process, FIG. 20 is a cross-sectional view taken along a line A6-A6 in FIG. 19, and FIG. 21 is a cross-sectional view taken along a line B6-B6 in FIG. 19.

A third insulating layer is coated on the substrate with the pattern as shown in FIG. 14, by a spin coating method, and then is patterned in a patterning process with a common mask plate, so as to form a pattern comprising the fourth via holes 24. Each fourth via hole 24 is positioned in a region where a drain electrode 7 is formed, and also located within a third via hole 23 opened in each common electrode 14. The third insulating layer 9 and the second insulating layer 8 within the fourth via hole 24 are removed by etching, to expose a surface of the drain electrode 7, as shown in FIGS. 19-21.

Finally, a second transparent conductive thin film is deposited on the substrate with the pattern as shown in FIG. 19, by a magnetron sputtering method or a thermal evaporating method, and is patterned in a patterning process with a common mask plate, so as to form a pattern comprising the pixel electrode 13 in the pixel region, and the pixel electrode 13 comprises the plurality of strip electrodes arranged in parallel and in sequence, and forms the multi-dimensional space composite field together with the common electrode 14. Each pixel electrode 13 is connected with a drain electrode 7 through one fourth via hole 24, and each strip electrode are connected with each other at their ends, the resultant production is shown in FIGS. 1-3. Since the area of the fourth via holes 24 is smaller than that of the third via holes 23, the insulation of the pixel electrodes 13 from the common electrodes 14 can be insured, and a short circuit between the pixel electrodes 13 and the common electrodes 14 does not occur.

It should be noted that, the above structure and preparation procedure is only one of the structures of the array substrate of the TFT-LCD of the disclosed technology, but the disclosed technology can be achieved by using different pattering processes and selecting different material or a combination thereof, in operation. For example, the first insulating layer, the second insulating layer, and the third insulating layer may comprise organic insulating layers or inorganic insulating layers. When inorganic insulating layers (e.g., oxide, nitride, or nitrogen oxide) are used, the deposition process may be performed by using a plasma enhanced chemical vapor deposition (PECVD) method. In another example, the first and second insulating layers may be inorganic insulating layers (e.g., silicon nitride), and the third insulating layer may be an organic layer (e.g., resin material). In still another example, the above described second patterning process may be implemented by a patterning process with two common mask plates, that is, the active layer pattern is formed by one patterning process with a common mask plate, and the data line pattern, the source electrode pattern, the drain electrode pattern, and the TFT channel region pattern are formed by another patterning process with a common mask plate.

The embodiment of the disclosed technology provides an array substrate of a TFT-LCD, in which the common electrodes are formed on the second insulating layer which covers the data lines, and the pixel electrodes with strip electrodes is formed on the third insulating layer which covers the common electrodes, so the edge portions of the pixel electrode are located over the data lines and overlapped with the data lines. Thus, the liquid crystal in a region between the edges of the pixel electrodes and the edges of the data lines is driven in the AD-SDS mode, the efficiency of driving the liquid crystal is improved; and such region becomes to a display region, so the area of the display region is maximized, and aperture ratio is effectively improved. Compared with the technology of using the resin passivation layer, the embodiment of the disclosed technology can employ the conventional apparatuses and processes, so the investment cost and the material cost can be saved, it is easy to implement the technology of the disclosed technology, and the production cost is lowered. Compared with the technology of changing the positions of the common electrode and the pixel electrode, the embodiment of the disclosed technology can be implemented by a six-mask processes, so aperture ratio is improved without increasing the preparation procedure and the production cost.

The method for manufacturing the array substrate of the ITT-LCD according to the embodiment of the disclosed technology comprises the following steps:

Step 1, forming a pattern comprising a gate line and a gate electrode on a substrate;

Step 2, forming a pattern comprising an active layer, a data line, a source electrode, and a drain electrode on the substrate after the above step;

Step 3, forming a second insulating layer comprising first and second via holes on the substrate after the above steps, the first via hole is positioned in a gate line bonding area, and the second via hole is positioned in a data line bonding area;

Step 4, forming a pattern comprising a common electrode, a gate connecting electrode, and a data connecting electrode on the substrate after the above steps, a third via hole is opened in the common electrode corresponding to the position of a drain electrode, the gate connecting electrode is connected with the gate line through the first via hole, and the data connecting electrode is connected with the data line through the second via hole;

Step 5, forming a third insulating layer on the substrate after the above steps, and forming a fourth via hole at the position of the drain electrode so as to expose a surface of the drain electrode, the fourth via hole is located within the third via hole;

Step 6, forming a pattern comprising a pixel electrode on the substrate after the above steps, the pixel electrode is connected with the drain electrode through the fourth via hole.

The embodiment of the disclosed technology provides a method for manufacturing an array substrate of a TFT-LCD, in which a common electrode is formed on a second insulating layer which covers a data line, and a pixel electrode with strip electrodes is formed on a third insulating layer which covers the common electrode, so edge of the pixel electrode is located over the data line and overlapped with the data line. Thus, liquid crystal in a region between the edge of the pixel electrode and the edge of the data line is driven in the AD-SDS mode, the efficiency of driving the liquid crystal is improved; and such region becomes to a display region, so the area of the display region is maximized, and aperture ratio is effectively improved.

In the above embodiments, an example of the step 1 comprises: depositing the gate metal thin film on the substrate, and forming the pattern comprising the gate line and the gate electrode by a patterning process with a common mask plate, the gate electrode is connected with the gate line.

In above embodiments, an example of the step 2 comprises:

Forming the first insulating layer, the semiconductor thin film, the doped semiconductor thin film and the source and drain metal thin film in order on the substrate after step 1;

Coating a photoresist layer on the source and drain metal thin film;

Exposing the photoresist by using a half-tone mask plate or a gray tone mask plate, the developed photoresist forms the completely remained photoresist region, the completely removed photoresist region, and the partially remained photoresist region, wherein the completely remained photoresist region corresponds to a region where the data line pattern, the source electrode pattern, and the drain electrode pattern are formed, the partially remained photoresist region corresponds to a region where the TFT channel region pattern between the source electrode and the drain electrode is defined, and the completely removed photoresist region corresponds to a region except for the above patterns.

Etching the source and drain metal thin film, the doped semiconductor thin film, and the semiconductor thin film in the completely removed photoresist region by a first etch process, to form the pattern comprising the active layer and the data line;

Removing the photoresist in the partially remained photoresist region by an ashing process, to expose the source and the drain metal thin film in this region;

Completely removing the source and drain metal thin film and the doped semiconductor thin film in the partially remained photoresist region by a second etch process, and etching a part of the thickness of the semiconductor thin film pattern, to form the source electrode pattern, the drain electrode pattern, and the TFT channel region pattern;

Removing the remaining photoresist.

In the above described embodiment, an example of step 3 comprises: forming a second insulating layer on the substrate after the above steps, by using a spin coating method or a PECVD method, then forming the pattern comprises the first and second via holes in the second insulating layer by a patterning process with a common mask plate, the first via hole is positioned in the gate line bonding area, the first and second insulating layers within the first via hole are removed to expose the surface of the gate line, the second via hole is positioned in the data line bonding area, the second insulating layer within the second via hole is etched to expose the surface of the data line.

In the above embodiment, an example of step 4 comprises: depositing the first transparent conductive thin film on the substrate after the above steps, by using a magnetron sputtering method or a thermal evaporating method, forming the pattern comprising the common electrode, the gate connecting electrode and the data connecting electrode in a patterning process with a common mask plate, the common electrode may cover the pixel region, the third via hole is formed in the region where the drain electrode is formed, the second insulating layer is exposed by the third via hole, the gate connecting electrode is formed in the gate line bonding area, covers the first via hole, and is connected with the gate line, and the data line connecting electrode is formed in the data bonding area, covers the second via hole, and is connected with the data line.

In the above embodiment, an example of step 5 comprises: forming one third insulating layer on the substrate after the above steps, by using a spin coating method or a PECVD method, then forming the pattern comprising the fourth via hole in a patterning process with a common mask plate, the fourth via hole is located at the position of the drain electrode, the area of the fourth via hole is smaller than that of the third via hole opened in the common electrode, the second and third insulating layers within the fourth via hole are etched to expose a surface of the drain electrode.

In the above embodiments, an example of the step 6 comprises: depositing the second transparent conductive thin film on the substrate after the above steps, by using a magnetron sputtering method or a thermal evaporating method, forming the pattern comprising the pixel electrode in a patterning process with a common mask plate, the pixel electrode comprises the plurality of strip electrodes arranged in parallel and in sequence. The pixel electrode is connected with the drain electrode through the fourth via hole, and strip electrodes are connected with each other at their ends.

The preparation procedure for manufacturing the array substrate of the TFT-LCD according to the embodiment of the disclosed technology has been described in detail with reference to the technologies shown in FIGS. 4-13, so the repeat is omitted.

In the above embodiments, the description is provided in which the common electrode 14 is formed as a plate-like electrode over the pixel region, for example. The common electrode 14 also may comprise a plurality of slits extending in parallel in each pixel region, these slits correspond to the strip electrodes of the pixel electrode; or the common electrode 14 also may comprise a plurality of strip electrodes extending in parallel, the space between these strip electrodes correspond to the strip electrodes of the pixel electrode in each pixel region.

It should be noted that: the above description is only for the purpose of explaining the technology of the disclosed technology but not for a limitation, although the disclosed technology has been described in detail with reference to the preferred embodiments, those skilled in the art should understand that change and alternation can be made in the technologies of the disclosed technology without depart from the spirit and scope of the disclosed technology.

What is claimed is:

1. An array substrate of a thin film transistor liquid crystal display, comprising:
a base substrate;
gate lines and data lines for defining pixel regions on the base substrate, wherein in each of the pixel regions, a common electrode and a pixel electrode having strip electrodes, which form a multi-dimensional space composite field in cooperation, and a thin film transistor are formed, and
wherein the common electrodes are formed on a second insulating layer which covers the gate lines, the data lines, and the thin film transistors, the pixel electrodes are formed on a third insulating layer which covers the common electrodes.

2. The array substrate of claim 1, wherein edge portions of the pixel electrodes are overlapped with the data lines and are positioned over the data lines.

3. The array substrate of claim 1, wherein each thin film transistors comprise a gate electrode, a source electrode, and a drain electrode, and
wherein the gate electrode is connected with one gate line, the source electrode is connected with one data line, the drain electrode is connected with the pixel electrode through a fourth via hole formed in the second and third insulating layers.

4. The array substrate of claim 3, wherein a third via hole is formed in the common electrode and covers the region where the fourth via hole is formed.

5. The array substrate of claim 1, wherein first and second via holes are formed in the second insulating layer corresponding to a gate line bonding area and a data line bonding area, respectively, and
wherein gate connecting electrodes are formed on the second insulating layer to be connected with the gate lines through the first via holes, data connecting electrodes are formed on the second insulating layer to be connected with the data lines through the second via holes, and the common electrodes, the gate connecting electrodes, and the data connecting electrodes are disposed in the same layer.

6. A method for manufacturing an array substrate of a thin film transistor liquid crystal display, comprising:
Step 1, forming gate lines and gate electrodes on a base substrate;
Step 2, forming data lines, and an active layer, source electrodes and drain electrodes of thin film transistors on the base substrate after step 1;
Step 3, forming a second insulating layer comprising first and second via holes on the base substrate after step 2, the first via holes are positioned in a gate line bonding area, and the second via holes are positioned in a data line bonding area;
Step 4, forming common electrodes, gate connecting electrodes, and data connecting electrodes on the base substrate after step 3, wherein third via holes are formed in the common electrodes at positions of the drain electrodes, the gate connecting electrodes are connected with the gate lines via the first via holes, and the data connecting electrodes are connected with the data lines via the second via holes;
Step 5, forming a third insulating layer on the base substrate after step 4, and forming fourth via holes in the third insulating layer at the positions of the drain electrodes so as to expose a surface of the drain electrodes, wherein the fourth via holes are located within the third via holes; and
Step 6, forming pixel electrodes on the base substrate after step 5, the pixel electrodes are connected with the drain electrodes through the fourth via holes.

7. The method of claim 6, wherein edge portions of the pixel electrodes are overlapped with the data lines and positioned over the data lines.

8. The method of claim 6, wherein the step 2 comprising:
forming a first insulating layer, a semiconductor thin film, a doped semiconductor thin film and a source and drain metal thin film in order on the base after the step 1;
coating a photoresist layer on the source and drain metal thin film;
exposing the photoresist by using a half-tone mask plate or a gray tone mask plate, wherein the developed photoresist forms a completely remained photoresist region, a completely removed photoresist region, and a partially remained photoresist region, and wherein the completely remained photoresist region corresponds to a region where data line pattern, a source electrode pattern, and a drain electrode pattern are formed, the partially remained photoresist region corresponds to a region where a channel region pattern between the source electrodes and the drain electrodes is formed, and the completely removed photoresist region corresponds to a region except for the above patterns;
etching the source and drain metal thin film, the doped semiconductor thin film, and the semiconductor thin film in the completely removed photoresist region by a first etch process, to form the active layer and the data lines;
removing the photoresist in the partially remained photoresist region by an aching process, to expose the source and drain metal thin film in the region;
completely etching the source and drain metal thin film and the doped semiconductor thin film in the partially remained photoresist region by a second etch process, and etching a part of a thickness of a semiconductor thin film pattern, to form the source electrode pattern, them drain electrode pattern, and them channel region pattern; and
removing remaining photoresist.

9. The method of claim 6, wherein the step 3 comprising: forming the second insulating layer on the substrate after the step 2, then forming the first and second via holes in the second insulating layer by a patterning process, the first via holes are positioned in a gate line bonding area, the first and second insulating layers within the first via holes are removed to expose a surface of the gate lines, the second via holes are positioned at the data line bonding areas, and the second insulating layer within the second via holes is removed to expose a surface of the data lines.

10. The method of claim 6, wherein the step 4 comprising: forming the first transparent conductive thin film on the substrate after the step 3, and then patterning the first transparent conductive thin film by a patterning process to form the common electrodes, the gate connecting electrodes and the data connecting electrodes and the third via holes in the common electrodes at the positions of the drain electrodes.

11. The method of claim 6, wherein the step 5 comprising: forming the third insulating layer on the substrate after the step 4, and then forming the fourth via holes in the third insulating layer by a patterning process, wherein the second and third insulating layers within the fourth via holes are etched to expose a surface of the drain electrodes.

12. The method of claim 6, wherein the step 6 comprising: depositing the second transparent conductive thin film on the substrate after the step 5, then patterning the second transparent conductive thin film by a patterning process to form the pixel electrodes in the pixel regions, wherein the pixel electrodes each comprise the plurality of strip electrodes arranged in parallel and in sequence, and are connected with the drain electrodes through the fourth via holes, and the strip electrodes are connected with each other through their ends.
